(19) United States
(12) Patent Application Publication
(10) Pub. No.: US 2021/0389465 A1
(43) Pub. Date: Dec. 16, 2021

(54) ELECTRONIC DEVICE, METHOD AND COMPUTER PROGRAM

(71) Applicant: Sony Semiconductor Solution Corporation, Kanagawa (JP)

(72) Inventor: Victor Belokonskiy, Zaventem (BE)

(73) Assignee: Sony Semiconductor Solution Corporation, Kanagawa (JP)

(21) Appl. No.: 17/279,494

(22) PCT Filed: Oct. 25, 2019
(86) PCT No.: PCT/EP2019/079149

§ 371 Date: Mar. 24, 2021

(30) Foreign Application Priority Data
Oct. 31, 2018 (EP) 18203620.2

(51) Int. Cl. G01S 17/894; H01S 5/42; H01S 5/026

(52) U.S. Cl. CPC G01S 17/894; H01S 5/026; H01S 5/423

(57) ABSTRACT

An electronic device having an array of illumination units, and multiple drivers, each driver being configured to drive a sub-array of the illumination units.

### TECHNICAL FIELD

The present disclosure generally pertains to the field of electronic devices, in particular imaging devices and methods for imaging devices.

### TECHNICAL BACKGROUND

A time-of-flight camera is a range imaging camera system that determines the distance of objects measuring the time-of-flight (ToF) of a light signal between the camera and the object for each point of the image. A time-of-flight camera thus receives a depth map of a scene. Generally, a time-off-light camera has an illuminator that illuminates a region of interest with modulated light, and a pixel array that collects light reflected from the same region of interest. As individual pixels collect light from certain parts of the scene, a time-of-flight camera may include a lens for imaging while maintaining a reasonable light collection area.

Additionally, indirect time-of-flight (iToF) cameras are known, which measure the phase-delay between modulated light and reflected light, e.g. infrared (IR) light. Phase data is obtained by correlating the reflected signal with a reference signal (modulation signal). A typical number of four frames is used to calculate the depth image, wherein different phase offsets are applied for each frame. The number of frames is not limited to four, but three frames are minimally required.

Although there exist illumination techniques for ToF cameras, it is generally desirable to provide better illumination techniques for a ToF camera.

### SUMMARY

According to a first aspect the disclosure provides an electronic device comprising an array of illumination units, and multiple drivers, each driver being configured to drive a sub-array of the illumination units.

According to a second aspect, the disclosure provides a time-of-flight camera comprising the electronic device according to a first aspect

According to a third aspect, the disclosure provides a method of driving an electronic device comprising an array of illumination units, and multiple drivers, the method comprising driving, with each of the multiple drivers, a respective sub-array of the illumination units.

Further aspects are set forth in the dependent claims, the following description and the drawings.

### BRIEF DESCRIPTION OF THE DRAWINGS

Embodiments are explained by way of example with respect to the accompanying drawings, in which:

FIG. 1 schematically illustrates the basic operational principle of a time-of-flight (ToF) camera;

FIG. 2A schematically illustrates an VCSEL illuminator comprising a Vertical cavity surface emitting laser (VCSEL) array and a driver for driving the VCSEL array;

FIG. 2B schematically illustrates the HFM signal that drives the VCSEL illuminator of FIG. 2A;

FIG. 3A schematically illustrates a cross-sectional view of the VCSEL illuminator described in FIG. 2A and an illumination field generated by the VCSEL illuminator;

FIG. 3B schematically illustrates a vertical beam profile of the illumination field 30 of FIG. 3A generated by the VCSEL illuminator;

FIG. 4 schematically illustrates an embodiment of VCSEL illuminator comprising a Vertical cavity surface emitting laser (VCSEL) array and multiple drivers for driving the VCSEL array;

FIG. 5 schematically illustrates an embodiment of multiphase HFM signals used for driving the VCSEL array of FIG. 4;

FIG. 6A schematically illustrates an embodiment of a cross-sectional view of the VCSEL illuminator described in FIG. 4 and an illumination field generated by the VCSEL illuminator;

FIG. 6B schematically illustrates an embodiment of a vertical beam profiles of the illumination field 50 of FIG. 6A generated by the VCSEL illuminator;

FIG. 7 schematically illustrates an embodiment of VCSEL illuminator comprising a Vertical cavity surface emitting laser (VCSEL) array, multiple column drivers and row enable switches for spot scanning illuminator; and

FIG. 8 schematically illustrates a timing diagram that is applied to the switches for controlling the VCSELs of the electrical line zones of the VCSEL illuminator of FIG. 7, as well as a modulation signal HFM that is applied to the VCSEL illuminator.

### DETAILED DESCRIPTION OF EMBODIMENTS

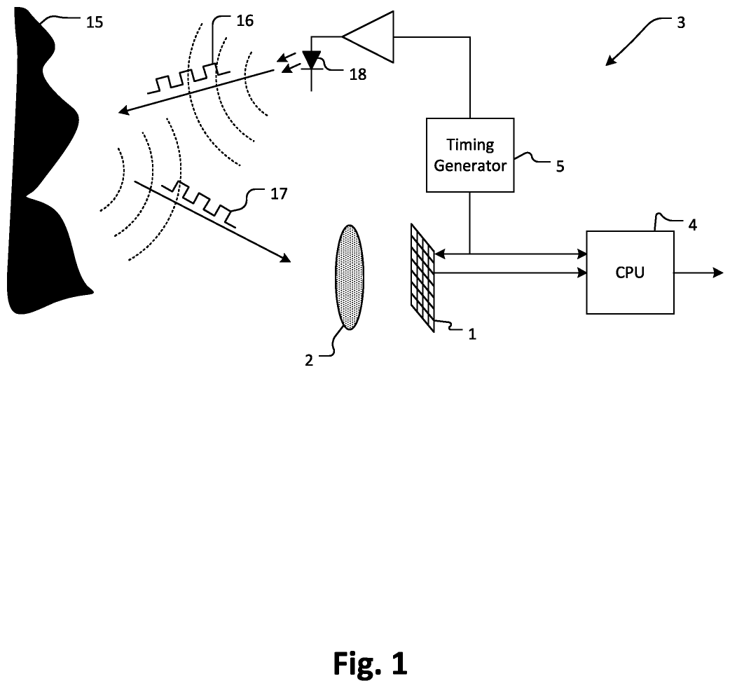

Before a detailed description of the embodiments under reference of FIG. 1, general explanations are made.

The embodiments described below provide an electronic device comprising an array of illumination units, and multiple drivers, each driver being configured to drive a sub-array of the illumination units.

The electronic device may be an illuminator for illuminating a scene. The electronic device may for example be an illuminator for a time of flight camera which is a range imaging camera that determines the distance of objects measuring the time of flight (ToF) of a light signal between the camera and the object for each point of the image. For example, an indirect time of flight camera (iToF) measures a phase delay which results from a correlation of the illumination signal with a reference signal. The electronic device may for example be a vertical cavity surface emitting laser (VCSEL) illuminator, an edge emitting laser, a LED, etc.

The array of illumination units may be a number of LEDs or laser diodes, in particular vertical-cavity surface-emitting lasers (VCSELs). The light emitted by the illumination units may be modulated with high speeds, e.g. from 200 MHz up to 300 MHz. The emitted light may be an infrared light to make the illumination unobtrusive.

The electronic device comprises multiple drivers, each driver being configured to drive a sub-array of the illumination units. The electronic device may for example comprise multiple drivers where each driver is associated with a subset of the illumination units. Each driver provides a modulated signal to the signal inputs of the associated illumination units. Driving an illumination unit of a time of flight camera with multiple drives may for example reduce a supply voltage and an electromagnetic interference (EMI). Further, the simplicity of the drivers may be increased. Therefore, a better balance between efficiency and switching speed may be obtained.

For example, driving the electronic device by grouping a number of N illumination units into multiple sub-arrays may lead to a reduction of an amplitude of the driving current by a factor of N. The average peak current during integration time (which defines the dimensions of the power supply) remains the same. The amount of filtering/decoupling circuitry is reduced by a factor N.

A sub-array of illumination units may comprise a set of one or more illumination units that are driven by the same driver. A sub arrays may be a subset of the array of illumination units. The illumination units of a sub-array may be arranged in any arbitrary form, e.g. in a rectangular region, or along a line.

By applying multiple drivers, the embodiments described below in more detail achieve a high peak optical power, e.g. 2 W to 10 W for the whole array, where the supply voltage may be low for each driver so that the supply voltage may be provided by a battery power. By achieving a high peak optical power, the quality of the electronic device is increased, e.g. by increasing the ambient light robustness and it may be possible to provide a wider field of view.

In some embodiment the illuminations units of the sub-arrays are grouped in respective electrical line zones.

The illuminations units which are grouped in an electrical line zones may be electrical connected to a respective driver and to a power supply. For example, the electrical line zones may be the columns or the rows of the array of illumination units.

In some embodiments the drivers are arranged to drive the sub-arrays according to a multiphase driving scheme.

Driving an electronic device by multiphase driving scheme may reduce an amplitude of a switching driving current, wherein the iToF modulation principles are retained as each zone has proper high frequency modulation (HFM), equivalent to full scene illumination. The switching driving current is the current that is applied to the illumination units of the electronic device. When a reduced switching driver current is applied to each of the electrical lines grouped in respective electrical line zones, the electromagnetic interference (EMI) towards the environment (i.e. the peak radiation from the whole device as measured at a certain distance) may be reduced.

The multiphase driving scheme may be used for high power infrared vertical-cavity surface-emitting laser (IR VCSEL) arrays used in indirect ToF depth cameras.

In some embodiments the drivers are arranged to drive the sub-arrays with high modulation frequency signals having a different phase offset.

Each high frequency modulation signal may have a phase different from a phase offset to the next HFM signal that is provided to the adjacent driver. The phase offset may for example be T/N wherein N is the number of drivers and T is the period of the HFM signal. The modulation signal may for example be a square wave with a frequency of 10 to 100 MHZ.

In some embodiments each electrical line zone is driven by a dedicated driver.

In some embodiments each sub-array of illumination units generates light of a dedicated optical line zone, where the optical line zones are not overlapping with adjacent optical line zone.

In some embodiments the optical line zones have a different phase offset.

For example, each of the optical line zones may be driven with a different phase offset so that the resulting optical line zones have a different phase offset. The optical line zones may for example have a T/N phase offset for each adjacent electrical line zones, where T, e.g. 10 ns, is the period of the HFM signals and N is the number of optical line zones.

In some embodiments the optical line zones have a constant illumination power.

In some embodiments multiphase modulation is used to implement spot scanning.

For example, each illumination unit of the electronic device may form a spot beam, where the spot beams of the illuminator are not overlapping.

In some embodiments, the electronic device further comprising circuitry for selecting sub-sets of illumination units, wherein each sub-set of illumination units is multiphase modulated.

The circuitry may for example comprise switches for selecting lines of illumination units at low frequency, wherein each line of illumination units is multiphase modulated. The multiple switches may be placed between the sub-arrays of illumination units and a power supply. By turning on and off the switches specific illumination units of each sub-array may be activated or deactivated.

In some embodiments the illumination units are vertical cavity surface emitting lasers.

The vertical-cavity surface-emitting laser, or VCSEL, is a type of semiconductor laser diode with laser beam emission perpendicular to the top surface. Each of the VCSEL may for example have an emitting power of 2 W to 10 W.

In some embodiments the electronic device is an illuminator for a time-of-flight camera.

In some embodiments the electronic device further comprising a diffractive optical element (DOE).

The diffractive optical element (DOE) may be disposed in front of the illumination unit array in order to shape and split the beams in an energy-efficient manner. A DOE may be a micro lens.

The embodiments also disclose a time-of-flight camera comprising the electronic device.

The embodiments also disclose a method of driving an electronic device comprising an array of illumination units, and multiple drivers, the method comprising driving, with each of the multiple drivers, a respective sub-array of the illumination units.

The methods as described herein are also implemented in some embodiments as a computer program causing a computer and/or a processor to perform the method, when being carried out on the computer and/or processor. In some embodiments, also a non-transitory computer-readable recording medium is provided that stores therein a computer program product, which, when executed by a processor, such as the processor described above, causes the methods described herein to be performed.

FIG. 1 schematically illustrates the basic operational principle of a time-of-flight (ToF) camera. The ToF camera 3 captures 3D images of a scene 15 by analyzing the time-of-flight of light from a dedicated illuminator 18 to an object. The ToF camera 3 includes a camera, for instance a 3D sensor 1 and a processor 4. A scene 15 is actively illuminated with a modulated light 16 at a predetermined wavelength using the dedicated illuminator 18, for instance with some light pulses of at least one predetermined frequency generated by a timing generator 5. The modulated light 16 is reflected back from objects within the scene 15. A lens 2 collects the reflected light 17 and forms an image of the objects onto the imaging sensor 1 of the camera. Depending on the distance of objects from the camera, a delay is experienced between the emission of the modulated light 16, e.g. the so-called light pulses, and the reception at the camera of those reflected light pulses 17. Distances between reflecting objects and the camera may be determined as function of the time delay observed and the speed of light constant value.

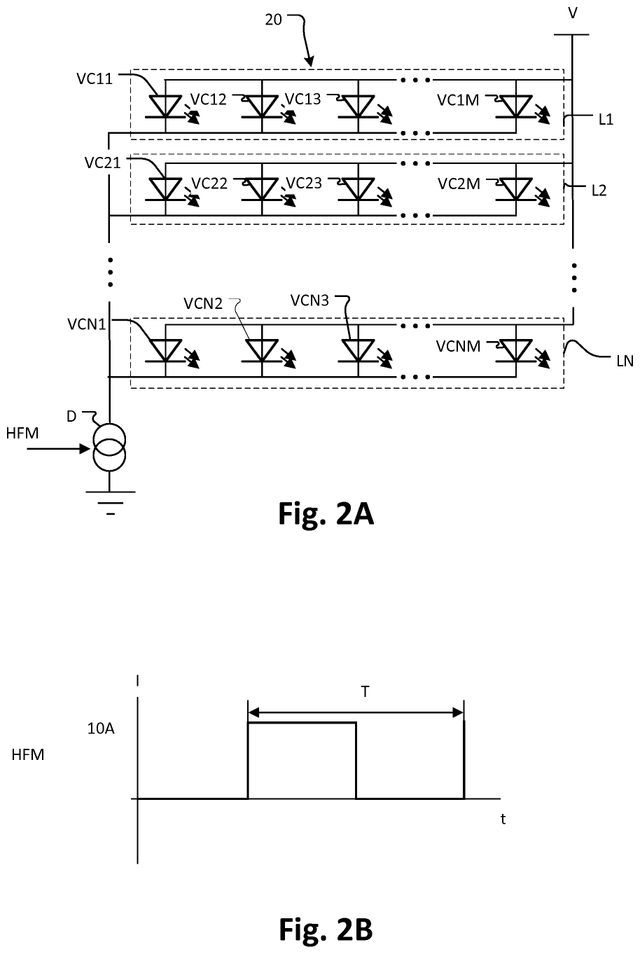

FIG. 2A schematically illustrates a VCSEL illuminator comprising a vertical cavity surface emitting laser (VCSEL) array and a driver for driving the VCSEL array. The VCSEL illuminator 20 comprises an array of VCSEL VC11-VCNM which are grouped in three electrical line zones L1-LN, a driver D for driving the VCSEL array. The electrical line zones L1-LN are the rows of the VCSEL array. The electrical line zone L1 comprises M VCSELs VC11-VC1M. The electrical line zone L2 comprises M VCSELs VC21-VC2M. The electrical line zone LN comprises M VCSELs VCN1-VCNM. Each electrical line zones L1-LN is connected to the driver D. A supply voltage V supplies the power for generating a driving current, where the driving current is the current that is applied to the driver D and to the VCSEL array. The driver D receives a high modulation frequency signal HFM to drive the VCSEL illuminator 20.

FIG. 2B schematically illustrates the HFM signal that drives the VCSEL illuminator of FIG. 2A. The HFM signal is a 50% duty cycle square wave with a high frequency, e.g. 100 MHz. A driving current with a high amplitude A of 10 ampere and a time period of T=0.01 μs (100 MHz) is used for the HFM signal. A driving current modulated with a high frequency of 100 MHz and a high amplitude of 10 ampere requires a large and bulky driver. FIG. 2B shows an HFM signal with a duty cycle of 50% and an amplitude of 10 amperes, however, the HFM signal is not limited thereto, other duty cycles and amplitudes may be applied, e.g. 1 to 10 A.

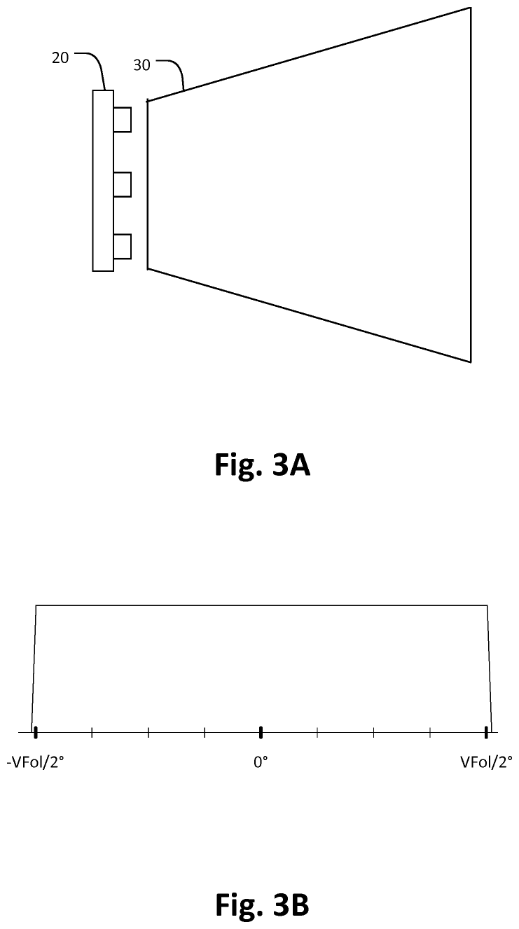

FIG. 3A schematically illustrates a cross-sectional view of the VCSEL illuminator described in FIG. 2A and an illumination field generated by the VCSEL illuminator. The illumination field 30 builds a common filed of illumination for illuminating a scene. A diffractive optical element (DOE) (not shown in FIG. 3A) is disposed in front of the VCSEL array 20 in order to shape and split the VCSEL beams in an energy-efficient manner.

FIG. 3B schematically illustrates a vertical beam profile of the illumination field 30 of FIG. 3A generated by the VCSEL illuminator. The beam generated by the VCSEL illuminator provides a vertical field of illumination VFoI®. The vertical beam profile extends from −VFoI/2° to VFoI/2°. In the schematic representation of FIG. 3B, the vertical beam profile has a constant illumination power.

### VCSEL Array Multiphase Modulation

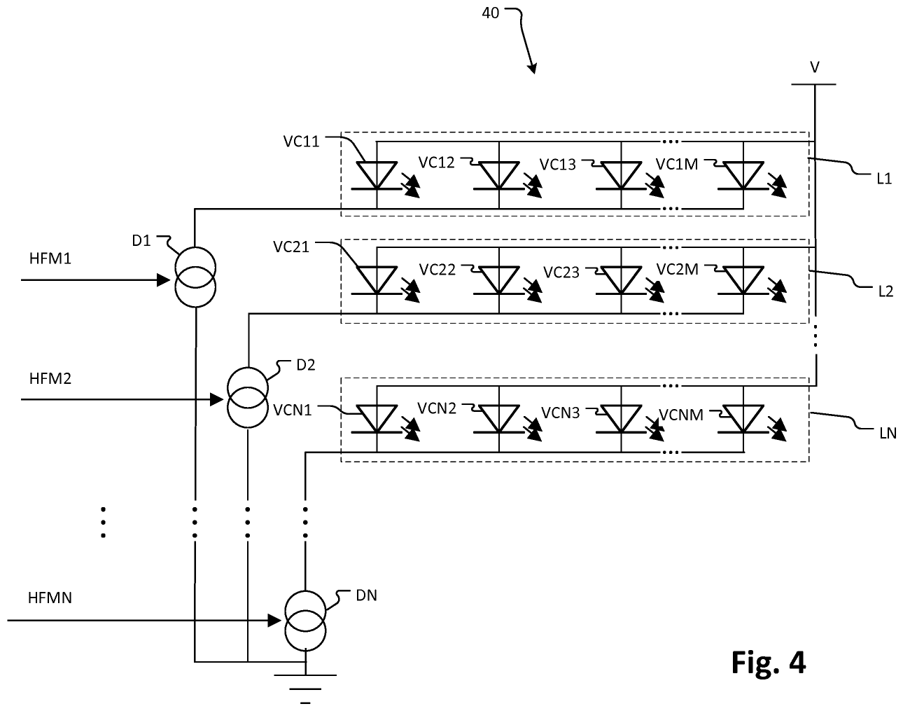

FIG. 4 schematically illustrates an embodiment of VCSEL illuminator comprising a vertical cavity surface emitting laser (VCSEL) array and multiple drivers for driving the VCSEL array. The VCSEL illuminator 40 comprises an array of VCSELs VC11-VCNM which are grouped in N sub arrays L1, L2, . . . , LN, N drivers D1, D2, . . . , DN for driving the VCSEL array and M VCSELs for each sub arrays L1, L2, . . . , LN, where N and M may for example be a number between 2 to 16 or any other number. Each VCSEL VC1N-VC3N may have an illumination power of 2 W to 10 W. In this embodiment, the sub-arrays L1, L2, . . . , LN correspond to the rows of the VCSEL array. The VCSELs VC11-VC1M of the first sub-array L1 are grouped in a first electrical line zone. The VCSELs VC21-VC2M of the second sub-array 12 are grouped in a second electrical line zone. The VCSELs VCN1-VCNM of the Nth sub-array LN are grouped in a Nth electrical line zone. Each electrical line zone is electrically connected to the respective driver D1, D2, . . . , DN and to a supply voltage V. The supply voltage V supplies the power for generating a driving current, where the driving current is the current that is applied to the drivers D1, D2, . . . , DN and to the VCSEL array. Each driver D1, D2, . . . , DN receives a respective high modulation frequency signal HFM1, HFM2, . . . , HFMN to drive the VCSEL illuminator 40.

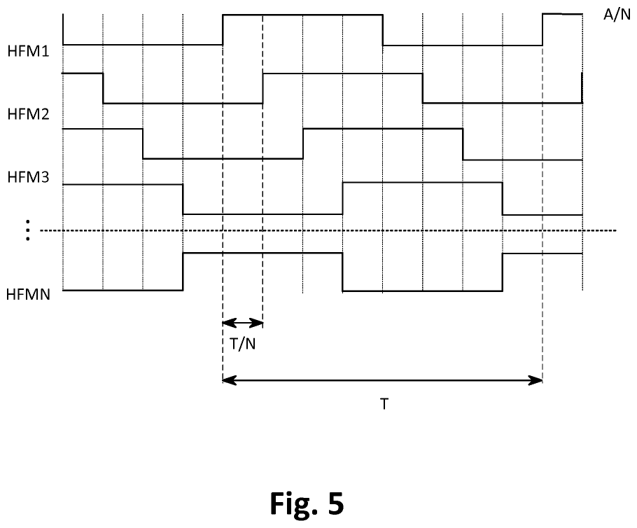

FIG. 5 schematically illustrates an embodiment of multiphase HFM signals used for driving the VCSEL array of FIG. 4. The HFM signals HFM1, HFM2, . . . , HFMN are 50% duty cycle square wave with a high frequency, e.g. 100 MHz. The HFM signals HFM1, HFM2, . . . , HFMN have a T/N phase offset for each adjacent electrical line zones, where T, e.g. 10 ns, is the period of the HFM signals and N is the number of electrical line zones. Driving the VCSEL illuminator 40 of FIG. 4 with different drivers (D1, D2, . . . , DN in FIG. 4) grouped in different sub-arrays (L1, L2, . . . , LN in FIG. 4) reduces the amplitude of the driving current by a factor of N, because a reduced number of VCSELs have to be driven by each driver. As a result, more simple and smaller drivers may be used compared to the driver that is used in the example of FIG. 2A and the influence of the electromagnetic interference (EMI) may be reduced. Therefore, a better balance between efficiency and switching speed may be obtained, wherein the iToF modulation principles are retained as each zone has proper HFM, equivalent to full scene illumination. FIG. 5 shows multiphase HFM signals with a duty cycle of 50%, however, the multiphase HFM signals is not limited thereto, other duty cycles may be applied.

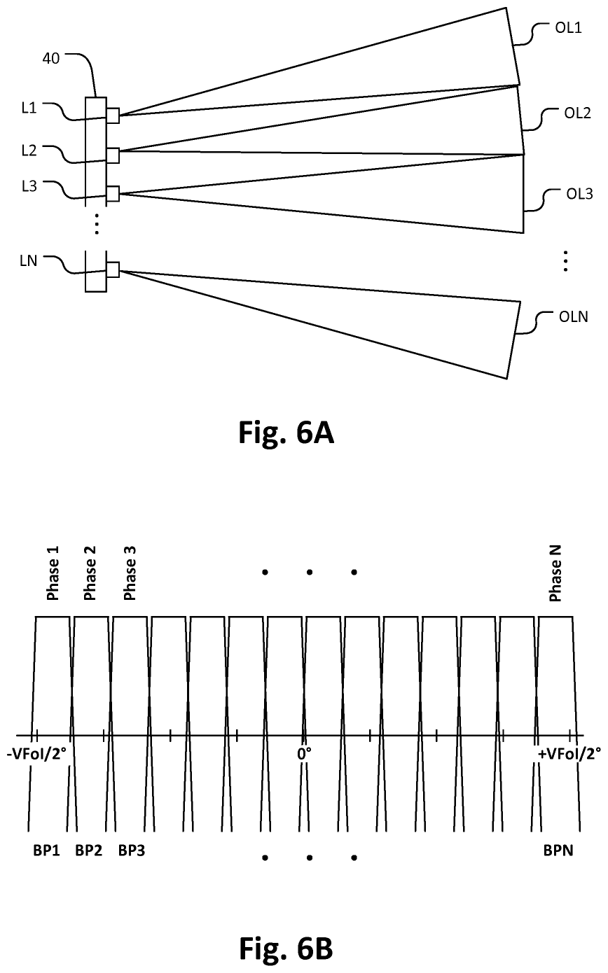

FIG. 6A schematically illustrates an embodiment of a cross-sectional view of the VCSEL illuminator described in FIG. 4 and an illumination field generated by the VCSEL illuminator. The illumination field 50 is generated by the VCSEL illuminator 40 as described in FIG. 4. Each line zone of the VCSEL illuminator 40 forms an optical line/beam OL1, OL2, . . . , OLN, where the optical lines/beams OL1, OL2, . . . , OLN are not overlapping to each other. The optical lines/beams OL1, OL2, . . . , OLN form together a field of illumination that is matching to a sensor's field of view (not shown in FIG. 6A). A diffractive optical element (DOE) (not shown in FIG. 6A) is disposed in front of the VCSEL array 40 in order to shape and split the VCSEL beams in an energy-efficient manner. A DOE may be or may include a micro lens. Each of the optical lines/beams OL1, OL2, . . . , OLN has a different phase that correspond to the phase offset shown in FIG. 5. For example, the first optical line/beam OP1 has a phase offset of T/N, the second optical line/beam OP2 has a phase offset of 2T/N, the third optical line/beam OP3 has a phase offset of 3T/N and the Nth optical line/beam OPN has a phase offset of 4T/N.

FIG. 6B schematically illustrates an embodiment of a vertical optical line/beam profiles of the illumination field of FIG. 6A generated by the VCSEL illuminator. The optical lines/beams generated by the VCSEL illuminator provide a vertical field of illumination VFoI®. The vertical optical lines/beam profiles extend from −VFoI/2° to VFoI/2°. In the schematic representation of FIG. 6B, the vertical optical line/beam profiles have a constant illumination power. Each of the optical line/beam has a different phase that correspond to the phase offset shown in FIG. 5. For example, the first beam profile BP1 has a phase offset of T, the second beam profile BP2 has a phase offset of T/2, the third beam profile BP3 has a phase offset of T/3 and the N beam profile has a phase offset of T/N.

### Spot Scan VCSEL Array Multiphase Modulation

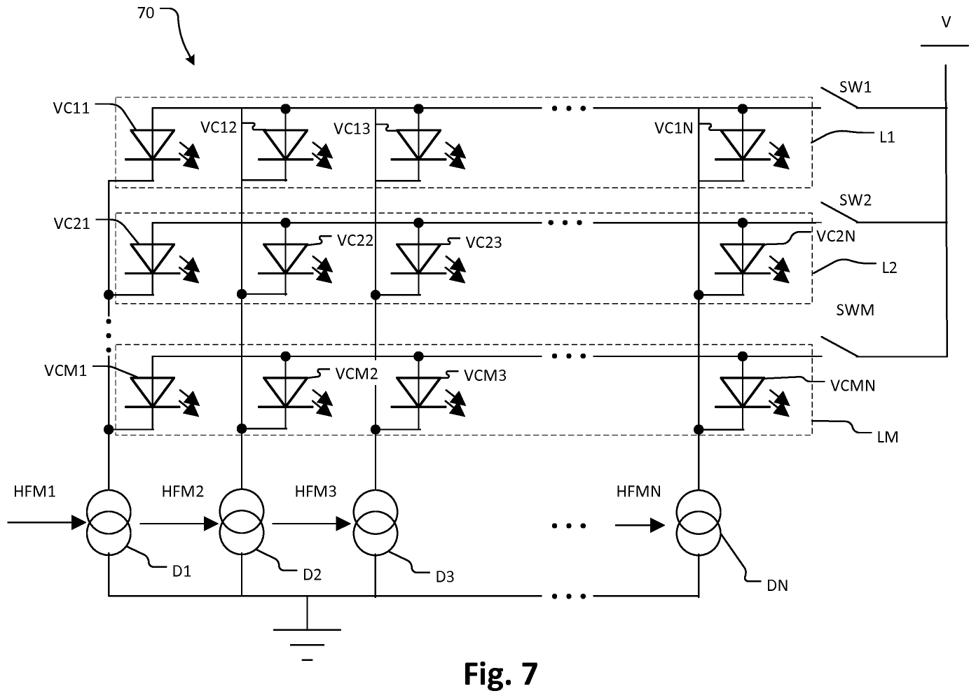

FIG. 7 schematically illustrates an embodiment of VCSEL illuminator comprising a vertical cavity surface emitting laser (VCSEL) array, column drivers and row enable switches for spot scanning illuminator. The VCSEL illuminator 70 comprises an array of VCSELs VC1N-VCMN which are grouped in M sub-sets L1-LM, N drivers D1, D2, . . . , DN for driving the VCSEL array, and M switches SW1-SWM, where N and M may for example be a number between 2 to 16 or any other number. Each VCSEL VC1N-VCMN may have an illumination power of 2 W to 10 W. In this embodiment the sub-sets L1-LM are the rows of the VCSEL array. The VCSELs VC11, VC12, . . . , VC1N, VC14 of the first sub-set L1 are grouped in the first electrical line zone. The VCSELs VC21, VC22, VC23, . . . , VC2N of the second sub-set 12 are grouped in the second electrical line zone. The VCSELs VC31, VC32, VC33, . . . , VC3N of the Mth sub-set LM are grouped in the third electrical line zone. Each electrical line zone is electrically connected to the respective driver D1, D2, . . . , DN and via the respective switches SW1-SWM to a supply voltage V. The supply voltage V supplies the power for generating a driving current, where the driving current is the current that is applied to the drivers D1, D2, . . . , DN and to the VCSEL array by turning on/off the respective switch SW1-SWM. Each driver D1, D2, . . . , DN receives a respective high modulation frequency signal HFM1, HFM2, . . . , HFMN to drive the VCSEL illuminator 70. Each controllable nodes of the illuminator 70 forms a spot beam, where the spot beams are not overlapping (not shown in FIG. 7). Each spot beam may for example a different phase offset. A diffractive optical element (DOE) (not shown in FIG. 6A) is disposed in front of the VCSEL array 70 in order to shape and split the VCSEL beams in an energy-efficient manner. A DOE may be a micro lens.

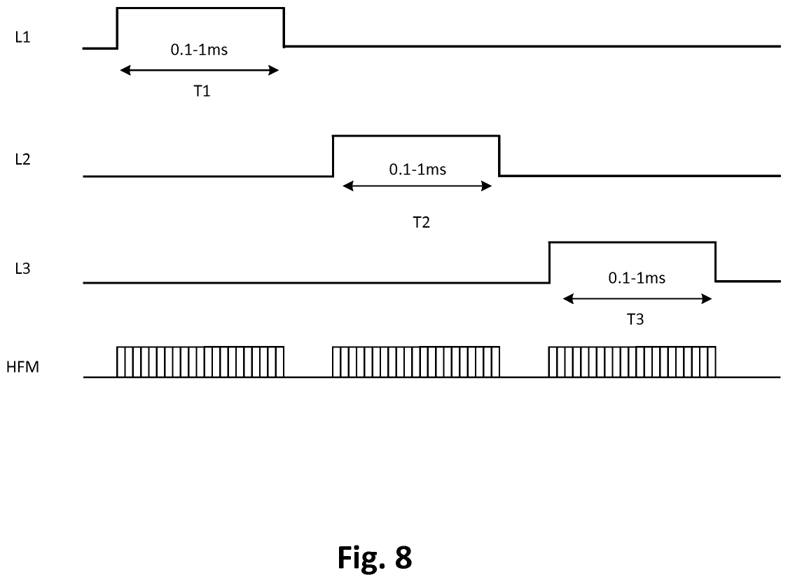

FIG. 8 schematically illustrates a timing diagram that is applied to the switches for controlling the VCSELs of the electrical line zones of the VCSEL illuminator of FIG. 7, as well as a modulation signal HFM that is applied to the VCSEL illuminator. Each line zone is selected to emit modulated light by turning on the respective switch (SW1, SW2, SW3 in FIG. 7) for a predetermined time interval T1, T2, and, respectively, T3. The time intervals T1, T2, T3 may for example last 0.1 to 1 ms. In the time interval T1 the first switch (SW1 in FIG. 7) is on so that the VCSELs of the first sub-array (L1 in FIG. 7) emit modulated light. In the time interval T2 the second switch (SW2 in FIG. 7) is on so that the VCSELs of the second sub-array (12 in FIG. 7) emit modulated light. In the time interval T3 the third switch (SW3 in FIG. 7) is on so that the VCSELs of the third sub-array (13 in FIG. 7) emit modulated light. Below the timing diagram it is shown the modulation signal HFM that is used for driving the VCSEL array. The modulation signal HFM has the same configuration as described in FIG. 5 above. The modulation signal HFM is repeated during the time intervals T1, T2, T3.

The methods for controlling an electronic device described in FIGS. 4 to 8 can also be implemented as a computer program causing a computer and/or a processor to perform the method, when being carried out on the computer and/or processor. In some embodiments, also a non-transitory computer-readable recording medium is provided that stores therein a computer program product, which, when executed by a processor, such as the processor described above, causes the method described to be performed.

All units and entities described in this specification and claimed in the appended claims can, if not stated otherwise, be implemented as integrated circuit logic, for example on a chip, and functionality provided by such units and entities can, if not stated otherwise, be implemented by software.

In so far as the embodiments of the disclosure described above are implemented, at least in part, using software-controlled data processing apparatus, it will be appreciated that a computer program providing such software control and a transmission, storage or other medium by which such a computer program is provided are envisaged as aspects of the present disclosure.

Note that the present technology can also be configured as described below.

(1) An electronic device (40; 70) comprising an array of illumination units (VC11-VCNM; VC1N-VCMN), and multiple drivers (D1, D2, . . . , DN), each driver (D1, D2, . . . , DN) being configured to drive a sub-array (L1, L2, . . . , LN) of the illumination units (VC11-VCNM; VC1N-VCMN).

(2) The electronic device (40; 70) of (1), wherein the illuminations units of the sub-arrays (L1, L2, . . . , LN) are grouped in respective electrical line zones.

(3) The electronic device (40; 70) of (1) or (2), wherein the drivers (D1, D2, . . . , DN) are arranged to drive the sub-arrays according to a multiphase driving scheme.

(4) The electronic device (40; 70) of anyone of (1) to (3), wherein the drivers (D1, D2, . . . , DN) are arranged to drive the sub-arrays with high modulation frequency signals (HFM1, HFM2, . . . , HFMN) having a different phase offset.

(5) The electronic device (40; 70) of (3), wherein each electrical line zone is driven by a dedicated driver (D1, D2, . . . , DN).

(6) The electronic device (40; 70) of anyone of (1) to (3), wherein each sub-array (L1, L2, . . . , LN) of illumination units generates light of a dedicated optical line zone (OL1, OL2, . . . , OLN), where the optical line zones (OL1, OL2, . . . , OLN) are not overlapping with adjacent optical line zone (OL1, OL2, . . . , OLN).

(7) The electronic device (40; 70) of (6), wherein the optical line zones (OL1, OL2, . . . , OLN) have a different phase offset.

(8) The electronic device (40; 70) of (6) or (7), wherein the optical line zones (OL1, OL2, . . . , OLN) have a constant illumination power.

(9) The electronic device (40; 70) of anyone of (1) to (8), wherein multiphase modulation is used to implement spot scanning.

(10) The electronic device (40; 70) of anyone of (1) to (9), further comprising circuitry (SW1-SWM) for selecting sub-sets of illumination units, wherein each sub-set of illumination units is multiphase modulated.

(11) The electronic device (40; 70) of anyone of (1) to (10), wherein the illumination units are vertical cavity surface emitting lasers (VC11-VCNM; VC1N-VCMN).

(12) The electronic device (40; 70) of anyone of (1) to (11), wherein the electronic device (40; 70) is an illuminator for a time-of-flight camera.

(13) The electronic device (40; 70) of anyone of (1) to (12), wherein the electronic device (40; 70) further comprising a diffractive optical element (DOE).

(14) A time-of-flight camera comprising the electronic device (40; 70) of anyone of (1) to (13).

(15) A method of driving an electronic device comprising an array of illumination units (VC11-VCNM; VC1N-VCMN), and multiple drivers (D1, D2, . . . , DN), the method comprising driving, with each of the multiple drivers (D1, D2, . . . , DN), a respective sub-array (L1, L2, . . . , LN) of the illumination units (VC11-VCNM; VC1N-VCMN).

(16) A computer program comprising program code causing a computer to perform the method of (15), when being carried out on a computer.

(17) A non-transitory computer-readable recording medium that stores therein a computer program product, which, when executed by a processor, causes the method according to (15) to be performed.

1. An electronic device comprising an array of illumination units, and multiple drivers, each driver being configured to drive a sub-array of the illumination units.

2. The electronic device of claim 1, wherein the illuminations units of the sub-arrays are grouped in respective electrical line zones.

3. The electronic device of claim 1, wherein the drivers are arranged to drive the sub-arrays according to a multiphase driving scheme.

4. The electronic device of claim 1, wherein the drivers are arranged to drive the sub-arrays with high modulation frequency signals having a different phase offset.

5. The electronic device of claim 3, wherein each electrical line zone is driven by a dedicated driver.

6. The electronic device of claim 1, wherein each sub-array of illumination units generates light of a dedicated optical line zone, where the optical line zones are not overlapping with adjacent optical line zone.

7. The electronic device of claim 6, wherein the optical line zones have a different phase offset.

8. The electronic device of claim 6, wherein the optical line zones have a constant illumination power.

9. The electronic device of claim 1, wherein multiphase modulation is used to implement spot scanning.

10. The electronic device of claim 1, further comprising circuitry for selecting sub-sets of illumination units, wherein each sub-set of illumination units is multiphase modulated.

11. The electronic device of claim 1, wherein the illumination units are vertical cavity surface emitting lasers.

12. The electronic device of claim 1, wherein the electronic device is an illuminator for a time-of-flight camera.

13. The electronic device of claim 1, wherein the electronic device further comprising a diffractive optical element.

14. A time-of-flight camera comprising the electronic device of claim 1.

15. A method of driving an electronic device comprising an array of illumination units, and multiple drivers, the method comprising driving, with each of the multiple drivers, a respective sub-array of the illumination units.
